(19) United States
(12) Patent Application Publication
(10) Pub. No.: US 2014/0283913 A1
(43) Pub. Date: Sep. 25, 2014

(54) Molybdenum Substrates for CIGS Photovoltaic Devices

(71) Applicant: Nanoco Technologies Ltd., Manchester (GB)

(72) Inventors: Stephen Whitelegg, Stockport (GB); Takashi Iwahashi, Tokyo (JP); Paul Kirkham, Lancashire (GB); Cary Allen, Manchester (GB); Zugang Liu, Kidlington (GB); Stuart Stubbs, Manchester (GB); Jun Lin, Tokyo (JP)

(73) Assignee: Nanoco Technologies Ltd., Manchester (GB)

(21) Appl. No.: 14/075,826

(22) Filed: Nov. 8, 2013

Related U.S. Application Data
(60) Provisional application No. 61/724,785, filed on Nov. 9, 2012.

(51) Int. Cl. H01L 31/0352; H01L 31/18

(52) U.S. Cl. CPC H01L 31/0352; H01L 31/18
USPC 136/260; 438/95; 136/252; 136/265; 136/262; 136/264

(57) ABSTRACT

Photovoltaic (PV) devices and solution-based methods of making the same are described. The PV devices include a CIGS-type absorber layer formed on a molybdenum substrate. The molybdenum substrate includes a layer of low-density molybdenum proximate to the absorber layer. The presence of low-density molybdenum proximate to the absorber layer has been found to promote the growth of large grains of CIGS-type semiconductor material in the absorber layer.

### BACKGROUND

1. Field of the Invention

This invention relates semiconductor nanoparticles. More particularly, it relates to methods and compositions for solution-phase formation CIGS films using nanoparticles.

2. Description of the Related Art including Information Disclosed under 37 CFR 1.97 and 1.98.

For widespread acceptance, photovoltaic cells (“PV cells,” aka. solar cells or PV devices) typically need to produce electricity at a cost that competes with that of fossil fuels. In order to lower these costs, solar cells preferably have low materials and fabrications costs coupled with increased light-to-electric conversion efficiency.

Thin films have intrinsically low materials costs since the amount of material in the thin (˜2-4 μm) active layer is small. Thus, there have been considerable efforts to develop high-efficiency thin-film solar cells. Of the various materials studied, chalcopyrite-based devices (Cu(In &/or Ga)(Se &, optionally S)2, referred to herein generically as “CIGS”) have shown great promise and have received considerable interest. The band gaps of CuInS2 (1.5 eV) and CuInSe2 (1.1 eV) are well matched to the solar spectrum, hence photovoltaic devices based on these materials are efficient.

Conventional fabrication methods for CIGS thin films involve costly vapor phase or evaporation techniques. A lower cost solution to those conventional techniques is to form thin films by depositing particles of CIGS components onto a substrate using solution-phase deposition techniques and then melting or fusing the particles into a thin film such that the particles coalesce to form large-grained thin films. This may be done using oxide particles of the component metals followed by reduction with H₂ and then by a reactive sintering with a selenium containing gas, usually H₂Se. Alternatively, solution-phase deposition may be done using prefabricated CIGS particles.

To form thin semiconductor films using CIGS-type particles (i.e., CIGS or similar materials), the CIGS-type particles preferably possess certain properties that allow them to form large grained thin films. The particles are preferably small. When the dimensions of nanoparticles are small the physical, electronic and optical properties of the particles may differ from larger particles of the same material. Smaller particles typically pack more closely, which promotes the coalescence of the particles upon melting.

Also, a narrow size distribution is important. The melting point of the particles is related to the particle size and a narrow size distribution promotes a uniform melting temperature, yielding an even, high quality (even distribution, good electrical properties) film.

In some cases it is necessary to modify the surface of the semiconductor particles with an organic ligand (referred to herein as a capping agent) to make them compatible with a solvent or ink that is used to deposit the particles on a substrate. In such cases, a volatile capping agent for the nanoparticles is generally preferred so that, upon relatively moderate heating, the capping agent may be removed to reduce the likelihood of carbon or other elements contaminating the final film upon melting of the nanoparticles.

Carbon and other contaminates within a CIGS film have been shown to limit the grain size of such films, and thereby reduce the quantum efficiency of PV devices based on such films. Consequently, there is a need to decrease carbon and other film contaminates and to increase the grain size of CIGS films. Hydrazine has been proposed as a carbon-free solvent for the deposition of CIGS particles for forming CIGS films. See D. B. Mitzi et al., Thin solid Films, 517 (2009) 2158-62. However, hydrazine is difficult to work with, is highly explosive, and consequently, its supply is subject to government controls and region-specific regulations. Air/oxygen annealing has been proposed to reduce the carbon concentration in the film. See E. Lee, et al., Solar Energy Materials & Solar Cells 95 (2011) 2928-32.

Conventional vacuum deposition techniques obviously avoid carbon contamination since solvents and capping agents are not employed. However, such vacuum techniques are hindered with the drawbacks described above.

Thus, a need exists for solution-deposited thin CIGS films having improved grain size and less contamination than the CIGS that are currently achievable using solution deposition techniques.

### SUMMARY

Generally, the disclosure describes PV devices and solution-based methods of making such PV devices. Such devices generally include a support, a molybdenum substrate, and a layer of photo-absorbing material disposed on the molybdenum substrate. Typically, the photo-absorbing material is a CIGS-type material, for example, a material having the formula AB₁₋ₓB′ₓC_{2-y}C′_{y}, where A is Cu, Zn, Ag or Cd; B and B′ are independently Al, In or Ga; C and C′ are independently S, Se or Te, 0≦x≦1; and 0≦y≦2.

The molybdenum substrate includes a low-density molybdenum layer, as described above. The low-density molybdenum layer typically has a thickness greater than about 500 nm and can have a thickness greater than about 800 nm. Generally the thickness is about 1000 nm, but it can be thicker. According to certain embodiments, the molybdenum substrate also includes a high-density molybdenum layer, which generally decreases the overall sheet resistance of the molybdenum substrate. The high-density molybdenum layer is generally situated between the low-density molybdenum layer and the support.

The methods of making the describe PV devices generally involve depositing a molybdenum substrate on a support and then using solution-based techniques to deposit nanoparticle precursors for a CIGS-type photo-absorbing layer on the molybdenum substrate. The photo-absorber precursor layer is then heated, typically in a Se-containing atmosphere, to melt the photo-absorber layer precursors and ideally form an absorber layer having large grains of CIGS-type material. The presence of low-density molybdenum in the molybdenum substrate promotes the formation of large grains of CIGS-type material.

The molybdenum substrate is typically deposited on a support by bombarding a molybdenum source with argon ions to sputter molybdenum onto the support. The density of the molybdenum layer formed in this manner can be adjusted by adjusting the pressure of argon used in the deposition process. Higher pressure of argon yields a lower-density (higher-resistance) molybdenum layer, while lower pressure yields higher-density layers. A method for determining the resistivity (and consequently, gauging the density) of molybdenum layers based on the intensity and width of x-ray diffraction (XRD) data of the molybdenum layers is described.

### BRIEF DESCRIPTION OF THE DRAWINGS

FIG. 1 is a schematic illustration of the layers of a PV device including a CIGS layer formed on a low-density molybdenum layer.

FIG. 2 is a flowchart illustrating steps for depositing a CIGS absorber layer.

FIG. 3 illustrates XRD traces of high-density (A), medium density (B), and low-density (C) molybdenum.

FIG. 4 is a graph of the relationship between resistivity of a molybdenum film and the peak intensity of the molybdenum peak in the XRD spectrum of the film.

FIG. 5 is a graph of the relationship between resistivity of a molybdenum film and the FWHM of the molybdenum peak in the XRD spectrum of the film.

FIG. 6 is an SEM micrograph of a CIGS PV device including a layer CuInSeS disposed on low-density molybdenum.

FIG. 7 are light and dark current v. voltage curves obtained using a PV device including a CIGS layers disposed on a low-density molybdenum layer.

FIGS. 8A and 8B SEM micrographs of a CIGS PV device including a layer of CuInSeS disposed on low-density molybdenum and on high-density molybdenum, respectively.

FIG. 9 is a schematic illustration of low-density molybdenum providing an impurity reservoir in a CIGS PV device.

FIG. 10 is a prior art support-substrate component having a low-density molybdenum adhesion layer and a high-density molybdenum layer.

FIG. 11 support-substrate component having a low-density molybdenum adhesion layer a high-density molybdenum layer and another low-density molybdenum layer.

### DETAILED DESCRIPTION

As used herein, “CIGS,” “CIS,” and “CIGS-type” are used interchangeably and each refer to materials represented by the formula AB₁₋ₓB′ₓC_{2-y}C′_{y}, where A is Cu, Zn, Ag or Cd; B and B′ are independently Al, In or Ga; C and C′ are independently S, Se or Te, 0≦x≦1; and 0≦y≦2. Example materials include CuInSe₂; CuInxGa₁₋ₓSe₂; CuGa₂Se₂; ZnInSe₂; ZnInxGa₁₋ₓSe₂; ZnGa₂Se₂; AgInSe₂; AgInₓGa₁₋ₓSe₂; AgGa₂Se₂; CuInSe_{2-y}S_{y}; CuInₓGa₁₋ₓSe_{2-y}S_{y}; CuGa₂Se_{2-y}S_{y}; ZnInSe_{2-y}S_{y}; ZnInₓGa₁₋ₓSe_{2-y}S_{y}; ZnGa₂Se_{2-y}S_{y}; AgInSe_{2-y}S_{y}; AgInₓGa₁₋ₓSe_{2-y}S_{y}; and AgGa₂Se_{2-y}S_{y}, where ≦x≦1; and 0≦y≦2.

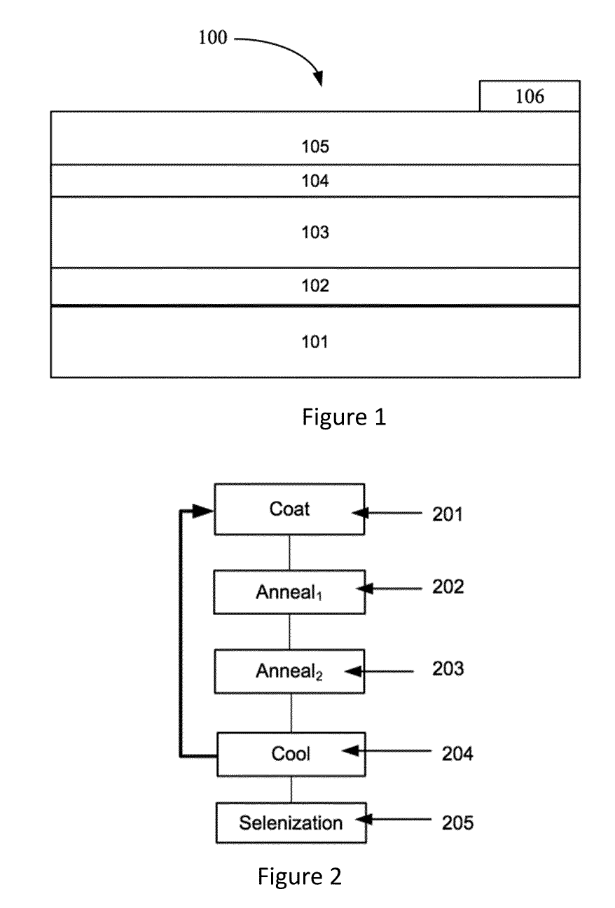

FIG. 1 is a schematic illustration of the layers of an exemplary PV device 100 based on a CIGS absorbing layer. The exemplary layers are disposed on a support 101. The layers are: a substrate layer 102 (typically molybdenum), a CIGS absorbing layer 103, a cadmium sulfide layer 104, an aluminum zinc oxide layer 105, and an aluminum contact layer 106. One of skill in the art will appreciate that a CIGS-based PV device may include more or fewer layers than are illustrate in FIG. 1.

Support 101 can be essentially any type of rigid or semi-rigid material capable of supporting layers 102-106. Examples include glass, silicon, and rollable materials such as plastics. Substrate layer 102 is disposed on support layer 101 to provide electrical contact to the PV device and to promote adhesion of CIGS absorption layer 103 to the support layer. Molybdenum has been found to be particularly suitable as a substrate layer 102.

The molybdenum substrate is typically prepared using a sputtering technique, for example, bombarding a molybdenum source with argon ions to sputter molybdenum onto a target (such as support 101). The density of the resulting molybdenum film can be adjusted by increasing or decreasing the processing pressure of the Ar sputter gas. At higher Ar pressures (>10 mTorr) collisions of the sputtered Mo atoms with the process gas reduce the energy of the Mo atoms, thereby increasing the mean free path and increasing the angle at which the Mo atoms impact the target. This leads to a build-up of tensile forces, which increases the porosity and intergranular spacing of the resulting Mo film. Decreasing the Ar pressure causes the resulting Mo film to become less porous and more tightly packed. As the Ar pressure is decreased further, compressive forces take over after the tensile stress reaches a maximum. High-density films prepared in this manner have been observed to have low resistivity (<1×10⁻⁴ Ω-cm), but strain in the films causes them to have poor adhesion to the support/target.

CIGS absorbing layer 103 is can include one or more layers of Cu, In and/or Ga, Se and/or S. CIGS absorbing layer may be of a uniform stoichiometry throughout the layer or, alternatively, the stoichiometry of the Cu, In and/or Ga, Se and/or S may vary throughout the layer. According to one embodiment, the ratio of In to Ga can vary as a function of depth within the layer. Likewise, the ratio of Se to S may vary within the layer.

According to the embodiment illustrated in FIG. 1, CIGS absorbing layer 103 is a p-type semiconductor. It may therefore be advantageous to include a layer of n-type semiconductor 104 within PV cell 100. Examples of suitable n-type semiconductors include CdS.

Top electrode 105 is preferably a transparent conductor, such as indium tin oxide (ITO) or aluminum zinc oxide (AZO). Contact with top electrode 105 can be provided by a metal contact 106, which can be essentially any metal, such as aluminum, nickel, or alloys thereof, for example.

Methods of depositing CIGS layers on a substrate are described in U.S. patent application Ser. No. 12/324,354, filed Nov. 26, 2008, and published as Pub. No. US2009/0139574 (referred to herein as “the '354 application”), the entire contents of which are incorporated herein by reference. Briefly, CIGS layers can be formed on a substrate by dispersing CIGS-type nanoparticles in an ink composition and using the ink composition to form a film on the substrate. The film is then annealed to yield a layer of CIGS material. FIG. 2 is a flow chart illustrating exemplary steps for forming layers of CIGS materials on a substrate using CIGS-type nanoparticle inks First (201), an ink containing CIGS-type nanoparticles is used to coat a film onto the substrate using a technique such as printing, spraying, spin-coating, doctor blading, or the like. Exemplary ink compositions are described in the '354 application.

One or more annealing/sintering steps (202, 203) are typically performed following the coating step (201). The annealing step(s) serve to vaporize organic components of the ink and other organic species, such as capping ligands that may present on the CIGS-type nanoparticles. The annealing step(s) also melt the CIGS-type nanoparticles. Following annealing, cooling the film (204) forms the CIGS layer, which preferably is made up of crystals of the CIGS material. The coating, annealing, and cooling steps may be repeated multiple times.

The CIGS material used in the ink composition is generally nanoparticles represented by the formula AB₁₋ₓB′ₓSe_{2-y}C_{y}, where A is Cu, Zn, Ag or Cd; B and B′ are independently Al, In or Ga; C is S or Te, 0≦x≦1; and 0≦y≦2 (note that if >0, then B′ B). According to some embodiments, the nanoparticles are of a first material having formula AB₁₋ₓB′ₓSe_{2-y}C_{y} and once the final annealing and cooling cycle is completed, the resulting layer is treated to convert the layer to a different material having a different formula according to AB₁₋ₓB′ₓSe_{2-y}C_{y}. For example, the nanoparticles may be of the formula CuInS₂, and the resulting layer of CuInS₂ can be treated with gaseous Se (205) to replace some of the sulfur with selenium, yielding a layer of CuInSe_{2-y}S_{y}.

It is generally desirable that the CIGS layer(s) of a PV device be composed of large grains of CIGS materials. Larger grains of material provide longer uniform charge-carrier path lengths and fewer grain boundaries, which impede charge-carrier mobility. Thus, grain growth of the CIGS material is generally seen as a prerequisite for high performance CIGS-type devices. Impurities, such as carbon, can be an inhibitor of grain growth of CIGS-type materials deposited from an organic solution.

It has been found that grain growth can be significantly improved by using low-density molybdenum as a substrate layer. Without being bound by theory, it is believed that the low-density molybdenum acts as a sink for impurities, such as carbon during the annealing/sintering process.

Low-density molybdenum has a microstructure consisting of porous columnar grains and contains significant intergranular voids. Films with this sputter-induced porosity demonstrate increased resistivity as a result of the porous microstructure. The magnitude and type of strain that is built up in the molybdenum film as it is deposited is related to the density of the film.

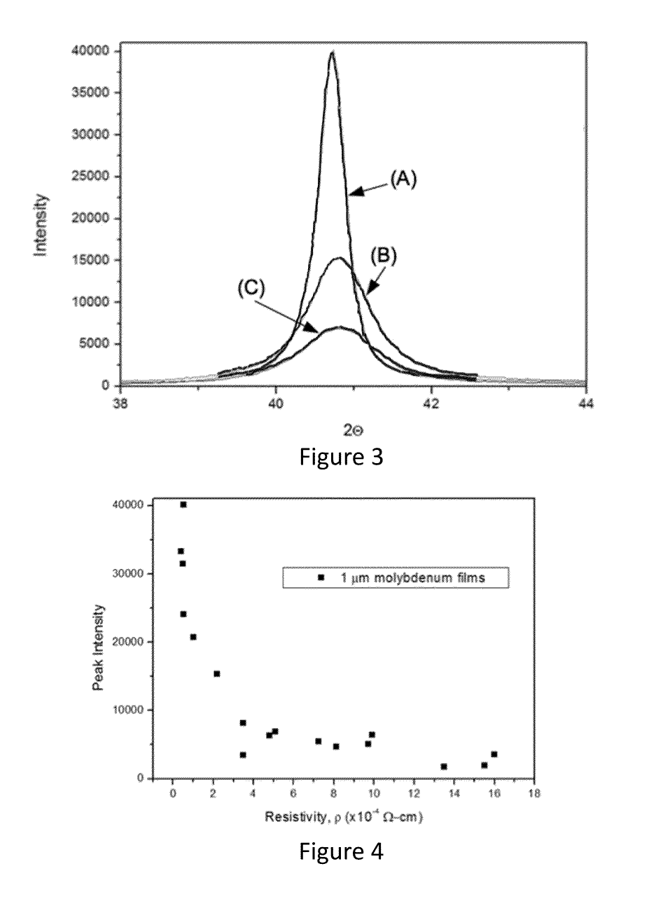

The peak intensity and FWHM of the x-ray diffraction (XRD) Mo peak are related to the Mo physical film parameters—density, grain size, and strain in the film. FIG. 3 shows XRD data for molybdenum films of varying density. FIG. 3A is the curve for high-density, 3B medium density, and 3 C low-density. The intensity of the XRD signal increases with increasing film density. Also, the primary 2 θ reflection angle shifts slightly for films of different densities. This indicates a change in the average lattice spacing in the direction normal to the plane of the film. The full width at half-maximum (FWHM) of lower density films (3C, for example) is widened in comparison to the higher density films, due to a decreasing grain size and a distribution of the lattice spacing or strain.

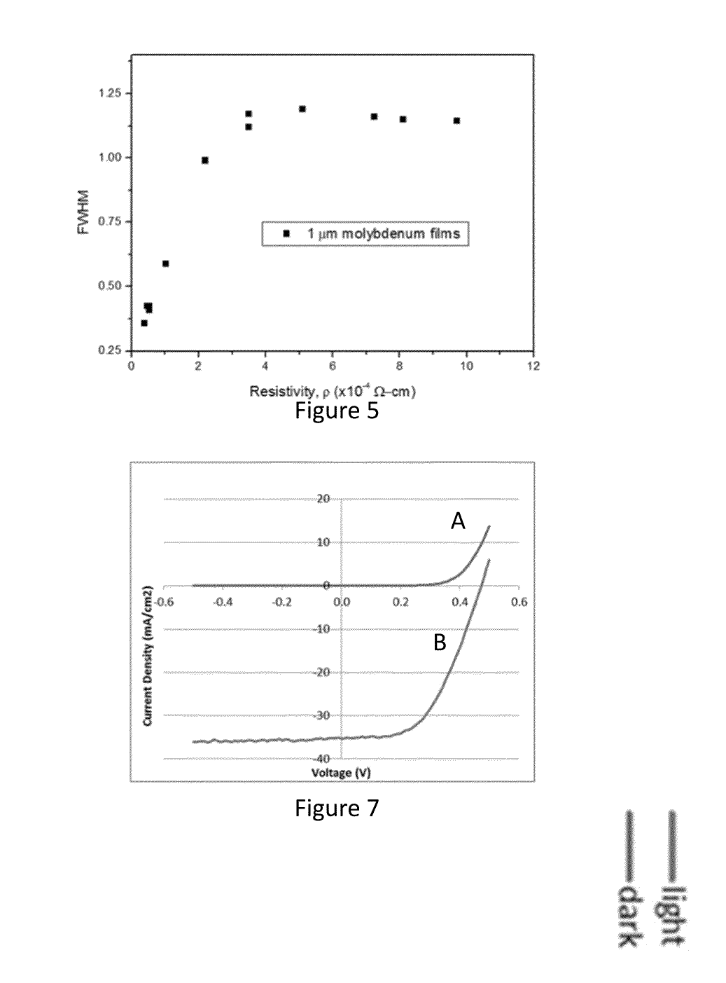

The peak intensity and FWHM of the Mo XRD peak are related to the resistivity of the film. FIGS. 4 and 5 show the experimentally determined relationship between resistivity and XRD peak intensity (FIG. 4) and resistivity and XRD peak FWHM (FIG. 5). The relationships illustrated in FIGS. 4 and 5 are equipment specific and must be determined for the specific equipment used to prepare the molybdenum film. Once determined, the relationships illustrated in FIGS. 4 and 5 can be used as control parameters for gauging molybdenum film density.

The size of nano-scale particles or crystallites in a solid is related to the width of the peak in an x-ray diffraction pattern. The Scherrer equation shown below can be used to estimate the grain size by measuring the Bragg angle, θ the broadening or FWHM of the peak, β, and knowing the x-ray wavelength, λ. As a number of factors can also influence the peak broadening (strain and instrumentation) the result of the Scherrer equation represents a lower limit to the crystal size as these other effects are neglected. In addition, the Scherrer equation is only valid for nano-scale particles and is usually not applied to grains that are larger than 100 nm; as a rule it is 20-30% accurate and only provides a lower bound on the particle size. (i.e. crystallites). The Scherrer formula is;

$$t = \frac{K * λ}{β * cos θ}$$

where K is known as the shape factor and depend upon crystallite shape (˜0.9).

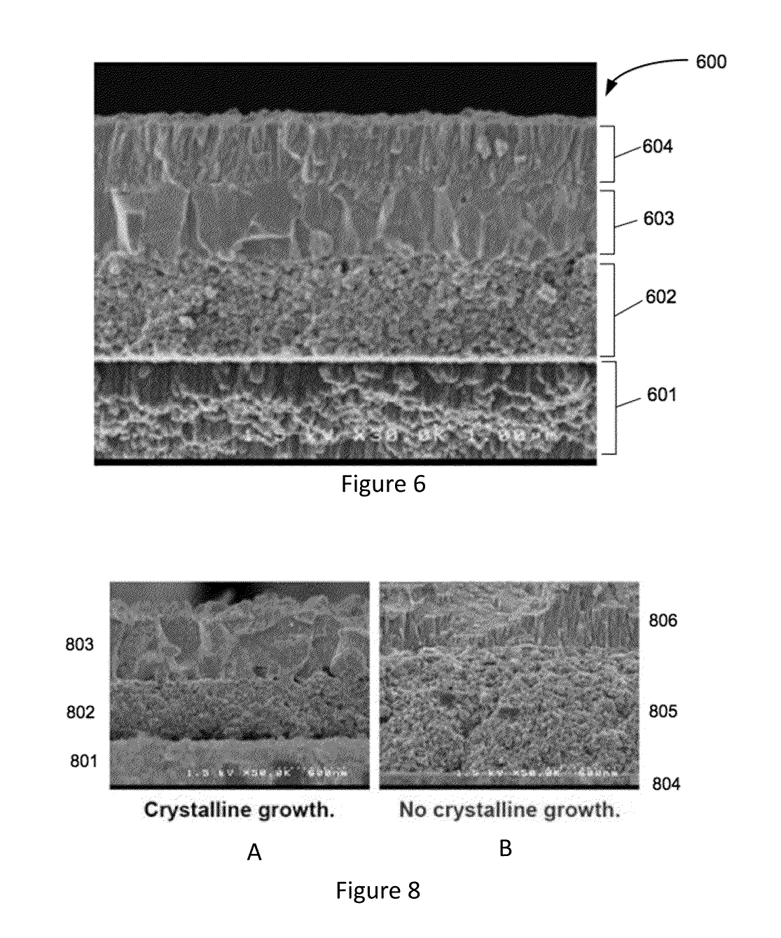

According to an exemplary embodiment, a molybdenum film is prepared in a sputter chamber that is first pumped down to a base pressure of <8×10⁻⁷ mbar, after which argon is introduced at a flow rate of 10 sccm and is controlled to a process pressure of 13-15 mT. After striking the plasma an initial “adhesion layer” is sputtered at a power density of 1.11 W/cm² with a thickness of 10 nm, after which the power density is increased to 1.66 W/cm² in 10 seconds to deposit a further 990 nm. The final thickness of the molybdenum films is set to 1 μm regardless of whether it is of high or low-density. This will result in a low-density molybdenum film exhibiting a resistivity 4×10⁻⁴ Ω-cm with an XRD peak FWHM of ˜1.2. FIGS. 6-8 (discussed in more detail below) illustrate SEM images and performance data for CIGS PV devices prepared with a low-density molybdenum substrate layer, prepared as described in Example 1 below.

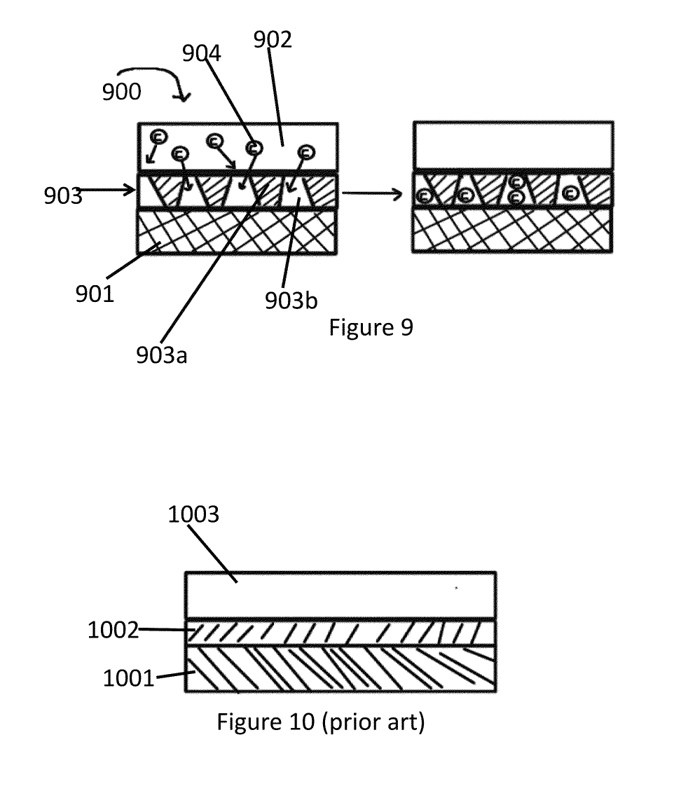

As stated above, it is believed that the low-density molybdenum promotes crystal formation in the CIGS layer by providing a sink for impurities during the sintering of the CIGS film. This mechanism is schematically illustrated in FIG. 9, which illustrates a PV device 900 having a substrate 901 and a CIGS absorber layer 902 formed on a low-density molybnenum layer 903. As described above, the low-density molybdenum layer 903 has a microstructure consisting of porous columnar grains 903a and contains significant intergranular voids 903b. The porosity and voids of low-density molybdenum layer 903 provides a reservoir for carbon 904 and other impurities in CIGS layer 902. When the device 900 is sintered, impurities 904 can escape layer 902 and collect in the low-density molybdenum layer 903. This escape promotes grain growth in CIGS layer 902.

The mechanism illustrated in FIG. 9 is supported by the secondary ion mass spectroscopy (SIMS). SIMS analysis of a high-density molybdenum layer that was used in a PV device, such as shown in FIG. 8B, (i.e., a device in which the CIGS layer does not exhibit large crystal growth) indicates that the high-density molybdenum layer is relatively free of carbon. In contrast, SIMS analysis of a low-density molybdenum layer used in a device as shown in FIG. 8A, (i.e., a device in which the CIGS layer does exhibit large crystal growth), indicates a high concentration of carbon sequestered in the molybdenum layer. This observation supports the hypothesis that the low-density molybdenum provides a reservoir for impurities, which promotes the purification of the CIGS layer during the sintering and selenization process, thereby promoting large grain growth. In other words, the low-density molybdenum layer absorbs appreciable carbon during the melting/sintering process. As used herein, the term “appreciable carbon” indicates that the amount of carbon in the molybdenum layer increases by at least about 10% compared to the amount of carbon present in the layer before scintering.

It will be noted that generally it is desirable to minimize the resistance of the molybdenum layer in a PV device. Low-density molybdenum intrinsically results in high sheet resistance, causing the PV device to have a high series resistance, reduced fill factor, and reduced power conversion efficiency. It is therefore counterintuitive to provide a molybdenum layer with a higher resistance than is obtainable. It is surprising that a lower density molybdenum layer, i.e., a molybdenum layer having a higher resistance, actually provides enhanced PV performance.

While it is generally considered preferable to minimize the resistance of the molybdenum layer in a PV cell, it has been recognized that certain high-density (low-resistance) molybdenum layers suffer from problems due to poor adhesion with the support. See, e.g., Sputtered molybdenum bilayer back contact for copper indium diselenide-based polycrystalline thin-film solar cells,” Scofield, et al., Thin Solid Films, 260 (1995) 26-31, the entire contents of which are incorporated herein by reference. As illustrated in FIG. 10 a layer of low-density molybdenum 1002 has been used in the past as an adhesion layer 1001. See Id. However, such an adhesion layer 1002 is typically is applied directly to the support 1001 and then a denser, less resistant layer 1003 is deposited on top of the low-density layer 1002, so as to minimize the resistance of the overall structure.

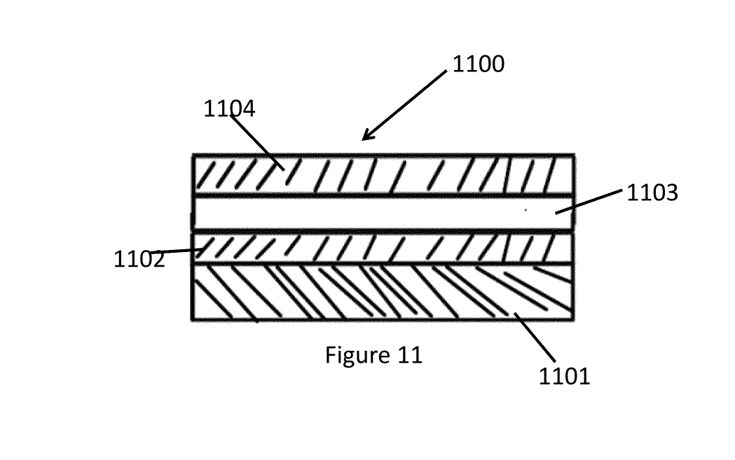

The structure illustrated in FIG. 10 is not optimized to facilitate grain growth, as described in the present disclosure because the high-density layer 1003 is not capable of absorbing and sequestering impurities from the CIGS layer(s), as described above. Thus, as an alternative embodiment of the disclosed devices has at least three layers of molybdenum, as illustrated in FIG. 11. The structure illustrated in FIG. 11 has a low-density layer of molybdenum 1102 deposited on support 1101. Low-density molybdenum layer 1102 serves as an adhesion layer. A layer of high-density molybdenum 1103 is deposited on layer 1102. The high-density layer 1103 serves to minimize the overall sheet resistance of the structure 1100. A second low-density molybdenum layer 1104 is deposited on the high-density layer 1103. The low-density layer 1104 serves as a reservoir for impurities released form the CIGS layer(s) (not shown), as described above.

It will be appreciated that one of the embodiments disclosed herein is a PV device having a CIGS-type material disposed on low-density molybdenum. As used herein, the term “low-density molybdenum layer” refers to a molybdenum layer having a resistivity of about 0.5×10⁻⁴ Ω-cm or more. Low-density molybdenum films may have even greater resistance, for example, resistances greater than about 2.0×10⁻⁴ Ω-cm, 2.5×10⁻⁴ Ω-cm, 3.0×10⁻⁴ Ω-cm, 4.0×10⁻⁴ Ω-cm, 5.0×10⁻⁴ Ω-cm, or even greater.

It will also be appreciated that such PV devices may also include one (or more) layers of high-density molybdenum, i.e., molybdenum having a resistivity of less than about 0.5×10⁻⁴ Ω-cm. The one or more layers of high-density molybdenum may be included to decrease the overall resistance of the molybdenum substrate. It will be recognized that adding one or more layers of high-density molybdenum will decrease the resistivity of the overall molybdenum structure. However, as used herein, the term “layer of high-density molybdenum” refers only to the portion of the molybdenum structure having high density (and therefore low resistance). In other words, a bilayer structure having a layer of high-density molybdenum and a layer of low-density molybdenum may have an overall resistivity of less than about 0.5×10⁻⁴ Ω-cm. But it will be apparent to a person of skill in the art that were the high-density and low-density molybdenum layers prepared individually, those layers would have a resistivity less than about 0.5×10⁻⁴ Ω-cm and more than about 0.5×10⁻⁴ Ω-cm, respectively.

Generally, the disclosure describes PV devices and solution-based methods of making such PV devices. Such devices generally include a support, a molybdenum substrate, and a layer of photo-absorbing material disposed on the molybdenum substrate. Typically, the photo-absorbing material is a CIGS-type material, for example, a material having the formula AB₁₋ₓB′ₓC_{2-y}C′_{y}, where A is Cu, Zn, Ag or Cd; B and B′ are independently Al, In or Ga; C and C′ are independently S, Se or Te, 0≦x≦1; and 0≦y≦2.

The molybdenum substrate includes a low-density molybdenum layer, as described above. The low-density molybdenum layer typically has a thickness greater than about 500 nm and can have a thickness greater than about 800 nm. Generally the thickness is about 1000 nm, but it can be thicker.

According to certain embodiments, the molybdenum substrate also includes a high-density molybdenum layer, which generally decreases the overall sheet resistance of the molybdenum substrate. The high-density molybdenum layer is generally situated between the low-density molybdenum layer and the support. The high-density layer is generally on the order of about 200 nm thick, in certain embodiments, though it may be thicker or less thick. The combination of high-density and low-density molybdenum provide a substrate having the beneficial, impurity-sequestering properties associated with low-density molybdenum, as described above, but also having low resistivity, due to the presence of high-density molybdenum. According to certain embodiments, the substrate combining a high-density molybdenum layer and a low-density molybdenum layer provide the substrate with a resistivity of less than about 0.5×10⁻⁴ Ω-cm.

The methods of making PV devices, as described above, generally involve depositing a molybdenum substrate on a support and then using solution-based techniques to deposit nanoparticle precursors for a CIGS-type photo-absorbing layer on the molybdenum substrate. The photo-absorber precursor layer is then heated, typically in a Se-containing atmosphere, to melt the photo-absorber layer precursors and ideally form an absorber layer having large grains of CIGS-type material. The presence of low-density molybdenum in the molybdenum substrate promotes the formation of large grains of CIGS-type material.

The molybdenum substrate is typically deposited on a support by bombarding a molybdenum source with argon ions to sputter molybdenum onto the support. As described above, the density of the molybdenum layer formed in this manner can be adjusted by adjusting the pressure of argon used in the deposition process. Higher pressure of argon yields a lower-density (higher-resistance) molybdenum layer, while lower pressure yields higher-density layers. A method is described above for determining the resistivity (and consequently, gauging the density) of molybdenum layers based on the intensity and width of x-ray diffraction (XRD) data of the molybdenum layers. One of skill in the art will appreciate how to use such measurements to form and monitor molybdenum layers of desired density using their own specific equipment. For the equipment used for the work described herein, argon pressures of greater than 10 mT provide relatively low-density (high resistivity) molybdenum layers, and argon pressures of less than about 5 mT provide high-density (low resistivity) layers.

The photo-absorber layer precursors typically include nanoparticles selected from the group of nanoparticles having the formula, AB, AC, BC, AB₁₋ₓB′ₓ, or AB₁₋ₓB′ₓC_{2-y}C′_{y}, where A is Cu, Zn, Ag or Cd; B and B′ are independently Al, In or Ga; C and C′ are independently S, Se or Te, 0≦x≦1; and 0≦y≦2. Solution-based methods of forming layers of such precursors are described in Applicant's co-owned patent applications, referenced above. The other components of a PV cell are constructed as known in the art.

### EXAMPLES

### Example 1

FIG. 6 shows an SEM of a cross section of a PV device 600 incorporating a low-density molybdenum substrate 601. Molybdenum coated soda-lime glass (2.5×2.5 cm) was used as the substrate. The glass support was cleaned prior to Mo deposition using a detergent such as Decon®, followed by a rinse with water and further cleaning with acetone and isopropanol, followed by a UV ozone treatment. A 1000 um low-density molybdenum was coated by RF sputtering at a pressure of 4 mT in Ar with a power of 40 W to confirm using a Moorfield minilab coater. Thin films of CuInS₂ are cast onto the substrate 601 by spin coating in a glovebox with a dry nitrogen atmosphere. The CuInS₂ film was deposited on the substrate using a multilayer technique. A total of 11 layers of CuInS₂ nanoparticles were used to fabricate a 1 um thick layer of CuInSe₂ nanoparticles. The first layer was cast onto the substrate using the 100 mg/ml solution in toluene, all subsequent layers were cast using the 200 mg/ml solution. For each layer a bead of CuInS₂ nanoparticle ink was deposited on to the substrate while stationary through a 0.2 μm PTFE filter. The substrate was then spun at 3000 rpm for 40 seconds. The sample was then transferred to a hotplate at 270° C. for 5 minutes, then transferred to a hotplate at 400° C. for 5 minutes; then transferred to a cold plate for >1 minute. The process was repeated for each CuInS layer. The 1 um CuInS₂ nanoparticle film was annealed in a H₂Se:N₂ containing atmosphere (˜5% wt H₂Se), using a tube furnace. The heating profile was ramp 10° C./min, Dwell 500° C. for 60 minutes; cool down using air assisted cooling ˜5° C./min. H2Se was flow was switch on and off at 400° C. When H₂Se was off the atmosphere in the tube furnace was 100% N₂. The film is etched in a KCN solution (10% wt.) for 3 minutes and then baked in air using a hotplate at 180° C. for 10 minutes. A buffer layer of cadmium sulfide (approximately 70 nm thickness) was deposited on top of the absorber layer chemical bath method. A conductive window layer of aluminium-doped zinc oxide (2% wt Al) with a thickness of 600 nm was sputter coated on top of the cadmium sulfide buffer layer. The ZnO:Al layer was then patterned using a shadow mask and a conductive grid of aluminium then deposited on top of the ZnO:Al window using a shadow mask and vacuum evaporation. The active area of the final PV device was 0.2 cm².

The completed PV device 600 includes a ˜1 um layer of p-type CuInSSe 602 and 603 on a 1 um layer of molybdenum 601 which is itself supported on a soda glass base support. On top of the CIGS layer is provided a thin 70 nm layer of n-type CdS (not visible in the SEM image) upon which has been deposited a 600 nm layer of ZnO:Al (2 wt %) 604, with 200 nm Al contacts provided thereon (not shown). The CuInSSe includes a large crystal region 603 and a small crystal region 602. The large grains of region 603 are clearly visible in the SEM.

FIG. 7 shows the current-voltage cures for PV device 600, wherein curve A is the dark current-voltage plot and curve B is the light current-voltage plot. PV device 600 has an open circuit voltage (V_{OC}) of 0.48 V, a short circuit current density (J_{SC}) of 35.36 mA/cm², and a fill factor (FF) of 50.3%.

FIG. 8 is a comparison of an SEM image of a CuInSSe deposited on a low-density molybdenum with an SEM image of a CuInSSe layer deposited on high-density molybdenum. In the sample with low-density molybdenum (A), both a small grain CuInSSe region 802 and a large grain CuInSSe region 803 are clearly visible on the low-density molybdenum substrate 801. In the sample with high-density molybdenum (B), only small grain CuInSSe (805) is observed on the high-density molybdenum 804. Note, in SEM 800B, layer 806 is ZnO:Al and is not crystals of CuInSSe.

### Example 2

Soda lime glass supports with dimensions 25 mm×25 mm were wet cleaned using detergent and organic solvents and then exposed to UV-ozone. The supports were then loaded into a Moorfield sputter coater chamber for molybdenum deposition using DC sputtering of a 99.95% pure molybdenum sputter target. The chamber was pumped down to an absolute pressure of <8×10⁻⁷ mbar before sputtering.

Argon was fed into the chamber at a flow rate of ˜10 sccm and the pressure of argon in the chamber is controlled using a gated valve and turbo pump. The molybdenum layers deposited using the following conditions:

For devices A1 and A2, a layer of high-density, highly conductive molybdenum, with a thickness of about 200 nm was deposited by sputtering at a pressure of 2-4 mT and a power density of ˜1.7 W/cm2. Then a layer of low-density molybdenum with a thickness of about 1000 nm was sputtered at a pressure of 10-15 mT at a power density of ˜1.7 W/m².

Devices B1 and B2 only included the layer of low-density molybdenum prepared. A layer of low-density molybdenum with a thickness of about 1000 nm was sputtered at a pressure of 10-15 mT at a power density of ˜1.7 W/m².

CIGS nanoparticle precursor solutions (CuInS₂) were then deposited via spin coating using a multilayer approach where the thickness of each layer is controlled through the concentration of the solution and the spin speed. 8-13 layers were spin coated to give a final absorber thickness of ˜1.6 μm and each layer was soft baked at 270° C. for 5 minutes followed by a hard bake at 415° C. for a further 5 minutes. The CIGS nanoparticle layer was reactive annealed under a hydrogen selenide and nitrogen gas mixture (˜5% H₂Se) in a tube furnace.

Solar cells were completed by etching the top layer with potassium cyanide (KCN), depositing a CdS buffer layer by chemical bath deposition, depositing an iZnO/ITO bilayer TCO using RF sputtering, and depositing an aluminium top contact using thermal vacuum evaporation.

The following table compares two cells having the three molybdenum layers (A1 and A2) with cells having only a single low-density layer (B1 and B2):

| | Rₛₕₑₑₜ | Voc | Jsc | Fill factor | | Rs |
|---|---|---|---|---|---|---|
| Sample | (Ω/□) | (V) | (mA/cm²) | (%) | PCE (%) | (Ω/cm²) |
| A1 | 1.3 | 0.49 | 37.2 | 56.2 | 10.4 | 4.5 |
| B1 | 2.2 | 0.49 | 31.3 | 42.5 | 6.4 | 9.4 |
| A2 | 1.3 | 0.47 | 33.4559 | 57.3902 | 9.060433 | 3.55 |
| B2 | 2.2 | 0.46 | 35.2602 | 53.59375 | 8.692741 | 3.76 |

As expected, the cells (A1 and A2) having three molybdenum layers, one of which is a high-density layer, have lower sheet resistance (Rₛₕₑₑₜ) than similar cells (B1 and B2) incorporating only a single, low-density molybdenum layer. The three layer-containing cells also have a higher short-circuit voltage (Jsc), fill factor, and efficiency (PCE) and have lower series resistance (Rs).

Although the present invention has been described with reference to specific details, it is not intended that such details should be regarded as limitations upon the scope of the invention. Modifications of the described embodiments will be apparent to those skilled in the art.

1. A structure, comprising:
support;
a first low-density molybdenum layer; and
a layer of photo-absorbing material disposed on, and proximate to, the low-density molybdenum.

2. The structure of claim 1, wherein the first low-density molybdenum layer has a resistivity of greater than about 2.0×10⁻⁴ Ω-cm.

3. The structure of claim 1, wherein the first low-density molybdenum layer has a resistivity of greater than about 3.0×10⁻⁴ Ω-cm.

4. The structure of claim 1, wherein the first low-density molybdenum layer has a resistivity of greater than about 4.0×10⁻⁴ Ω-cm.

5. The structure of claim 1, wherein the first low-density molybdenum layer has a resistivity of greater than about 5.0×10⁻⁴ Ω-cm.

6. The structure of claim 1, wherein the first low-density molybdenum layer has a thickness greater than about 500 nm.

7. The structure of claim 1, wherein the first low-density molybdenum layer has a thickness greater than about 800 nm.

8. The structure of claim 1, further comprising a high-density molybdenum layer.

9. The structure of claim 8, wherein the high-density molybdenum layer is situated between the low-density molybdenum layer and the support.

10. The structure of claim 8, wherein the high-density molybdenum layer has a resistivity of less than 0.5×10⁻⁴ Ω-cm.

11. The structure of claim 8, wherein the high-density molybdenum layer has a resistivity of less than 0.2×10⁻⁴ Ω-cm.

12. The structure of claim 8, wherein the high-density molybdenum layer and the low-density molybdenum layer are combined as a combined molybdenum layer having a resistivity of less than about 0.5×10⁻⁴ Ω-cm.

13. The structure of claim 8, further comprising a second low-density molybdenum layer disposed proximate to the support.

14. The structure of claim 8, further comprising a second low-density molybdenum layer disposed between the high-density molybdenum layer and the support.

15. The structure of claim 8, wherein the first low-density molybdenum layer, the high-density molybdenum layer, and the second low-density molybdenum layer are combined as a combined molybdenum layer having a resistivity of less than about 0.5×10⁻⁴ Ω-cm.

16. The structure of claim 1, wherein the low-density molybdenum layer is situated to absorb contaminants generated in the photo-absorbing material.

17. The structure of claim 16, wherein in the contaminants are organic contaminants.

18. The structure of claim 16, wherein in the contaminants are generated when the structure is heated to melt the photo-absorbing layer.

19. The structure of claim 1, wherein the low-density molybdenum layer contains appreciable carbon.

20. The structure of claim 1, wherein the photo-absorbing layer comprises a material having the formula AB₁₋ₓB′ₓC_{2-y}C′_{y}, where A is Cu, Zn, Ag or Cd; B and B′ are independently Al, In or Ga; C and C′ are independently S, Se or Te, 0≦x≦1; and 0≦y≦2.

21. A method of making a photovoltaic device, the method comprising:
depositing a low-density molybdenum layer on a support,
depositing a photo-absorber precursor layer on the low-density molybdenum layer, the photo-absorber precursor layer comprising nanoparticles and at least one organic component, wherein the nanoparticles are selected from the group of nanoparticles having the formula, AB, AC, BC, AB₁₋ₓB′ₓ, and AB₁₋ₓB′ₓC_{2-y}C′_{y}, where A is Cu, Zn, Ag or Cd; B and B′ are independently Al, In or Ga; C and C′ are independently S, Se or Te, 0≦x≦1; and 0≦y≦2.

22. The method of claim 21, wherein the low-density molybdenum layer has a resistivity of greater than about 2.0×10⁻⁴ Ω-cm.

23. The method of claim 21, wherein the low-density molybdenum layer has a resistivity of greater than about 3.0×10⁻⁴ Ω-cm.

24. The method of claim 21, wherein the low-density molybdenum layer has a resistivity of greater than about 4.0×10⁻⁴ Ω-cm.

25. The method of claim 21, wherein the low-density molybdenum layer has a resistivity of greater than about 5.0×10⁻⁴ Ω-cm.

26. The method of claim 21, wherein the low-density molybdenum layer has a thickness greater than about 500 nm.

27. The method of claim 21, wherein the at least one organic compound comprises a capping agent.

28. The method of claim 21, further comprising heating the photo-absorber precursor layer to melt the nanoparticles, whereby a portion of the at least one organic compound becomes absorbed into the low-density molybdenum layer.

29. A method of making a photovoltaic device, the method comprising:
depositing a first low-density molybdenum layer on a support,
depositing a high-density molybdenum layer on the first low-density molybdenum layer,
depositing a second low-density molybdenum layer on the high-density molybdenum layer, and
depositing a photo-absorber precursor layer on the second low-density molybdenum layer, the photo-absorber precursor layer comprising nanoparticles and at least one organic component, wherein the nanoparticles are selected from the group of nanoparticles having the formula, AB, AC, BC, AB₁₋ₓB′ₓ, or AB₁₋ₓB′ₓC_{2-y}C′_{y}, where A is Cu, Zn, Ag or Cd; B and B′ are independently Al, In or Ga; C and C′ are independently S, Se or Te, 0≦x≦1; and 0≦y≦2.

30. The method of claim 29, wherein the second low-density molybdenum layer has a resistivity of greater than about 2.0×10⁻⁴ Ω-cm.

31. The method of claim 29, wherein the second low-density molybdenum layer has a resistivity of greater than about 4.0×10⁻⁴ Ω-cm.

32. The method of claim 29, wherein the second low-density molybdenum layer has a thickness greater than about 500 nm.

33. The method of claim 29, wherein the high-density molybdenum layer has a resistivity of less than 0.2×10⁻⁴ Ω-cm.

34. The structure of claim 29, wherein the first low-density molybdenum layer, the high-density molybdenum layer, and the second low-density molybdenum layer are combined as a combined molybdenum layer having a resistivity of less than about 0.5×10⁻⁴ Ω-cm.
